(19) United States
(12) Patent Application Publication
(10) Pub. No.: US 2007/0232051 A1
(43) Pub. Date: Oct. 4, 2007

(54) Method for forming metal bumps

(75) Inventors: Sheng-Ming Wang, Taoyuan City (TW); Shuo-Hsun Chang, Zhongli City (TW); Kuo-Hua Chang, Zhongli City (TW); Chi-Chih Huang, Taipei City (TW); Chih-Cheng Chen, Guishan Shiang (TW)

Correspondence Address: RABIN & Berdo, PC, 1101 14TH STREET, NW, SUITE 500, WASHINGTON, DC, 20005, US

(73) Assignee: ADVANCED SEMICONDUCTOR ENGINEERING INC., Kaohsiung (TW)

(21) Appl. No.: 11/589,714

(22) Filed: Oct. 31, 2006

(30) Foreign Application Priority Data
Mar. 16, 2006 (TW) 95109039

(51) Int. Cl. H01L 21/44

(52) U.S. Cl. 438/612; 257/E23.021

(57) ABSTRACT

A method for forming metal bumps is disclosed, comprising: providing a substrate including a plurality of pads; forming a solder mask on the substrate, wherein the solder mask has first openings to expose the pads; forming a photoresist layer on the solder mask, wherein the photoresist layer has second openings to expose the pads; forming a conductive layer on the phototresist layer, wherein a sidewall of each second opening, a sidewall of each first opening and the pads are covered with the conductive layer; forming a metal layer on the conductive layer by electroplating to fill the first and second openings; performing a planarization step to remove the conductive layer and the metal layer on the photoresist layer so as to remain the conductive layer and the metal layer in the first and second openings; removing the photoresist layer and performing a reflow step to form metal bumps.

### RELATED APPLICATIONS

The present application is based on, and claims priority from, Taiwan Application Serial Number 95109039, filed Mar. 16, 2006, the disclosure of which is hereby incorporated by reference herein in its entirety.

### FIELD OF THE INVENTION

The present invention relates to a method for forming metal bumps, and more particularly, to a method for forming metal bumps for a fine pitch package process.

### BACKGROUND OF THE INVENTION

FIGS. 1A through 1E are schematic flow diagrams showing the conventional process for manufacturing metal bumps. As shown in FIG. 1A, a substrate 100 is initially provided, wherein the substrate 100 includes a plurality of pads 102 formed thereon. Next, a patterned solder mask 110 is formed on the substrate 100. In the method of forming the patterned solder mask 110, a solder mask 110 is deposed to cover the substrate 100, and a patterning step is performed to form a plurality of first openings 112 to expose the pads 102, wherein the patterning step includes exposure and development, for example. A conductive layer 120 is formed on the patterned solder mask 110, wherein the conductive layer 120 covers a sidewall of each first opening 112 of the patterned solder mask 110 and the pads. As shown in FIG. 1B, a patterned photoresist layer 130 is formed on the conductive layer 120, wherein the patterned photoresist layer 130 includes a plurality of second openings 132 to expose the conductive layer 120. In the forming of the patterned photoresist layer 130, a layer of photoresist is formed on the conductive layer 120, and then the plurality of openings 132 are formed by a patterning step (such as an exposing and developing step), so as to expose a portion of the conductive layer 120. Next, such as shown in FIG. 1C, a metal layer 140 is formed on the exposed conductive layer 120 to fill up the first openings 112 and to partially fill the first openings 132 by plating. As shown in FIG. 1D, the patterned photoresist layer 130 is removed to expose the remaining conductive layer 120 and the metal layer 140. Subsequently, a blank etching treatment is performed on the remaining conductive layer 120 and the metal layer 140. The thickness of the conductive layer 120 is very small, so that the conductive layer 120 is etched away rapidly, and the metal layer 140 and the conductive layer 120 underlying the metal layer 140 remain, such as shown in FIG. 1D. As shown in FIG. 1E, a reflow step is performed to make the remaining conductive layer 120 and the metal layer 140 forms a plurality of metal bumps 150.

In the aforementioned prior art, the uniformity of the thickness of the metal layer 140 formed by plating is poor and the uniformity of the sizes of the metal bumps 150 is poor, so that the yield of the products is decreased in the package process. In the current package process that require a fine pitch, the quality of the products manufactured by the prior art method cannot meet customer requirements and enhancing the product yield of the package process is difficult, thereby increasing the cost.

### SUMMARY OF THE INVENTION

Therefore, an improved method for forming metal bumps is desired to solve the problems including the increasing of the process cost and the decreasing of the product yield in the prior art, thereby enhancing the process yield and lowering the process cost.

One aspect of the present invention is to provide a method for forming metal bumps, with using plating to form a metal layer to completely fill up second openings and then performing a planarization step to planarize the metal layer to ensure that the metal layer in the second openings has a substantially identical height. Accordingly, the poor uniformity in sizes of the metal bumps resulting from the unequal height of the metal layers can be solved.

According to the aforementioned aspect, the present invention provides a method for forming metal bumps, comprising: providing a substrate including a plurality of pads; forming a patterned solder mask on the substrate, wherein the patterned solder mask has a plurality of first openings to expose the pads; forming a patterned photoresist layer on the patterned solder mask, wherein the patterned photoresist layer has a plurality of second openings to expose the pads; forming a conductive layer on the patterned phototresist layer, wherein a sidewall of each second opening in the patterned photoresist layer, a sidewall of each first opening in the solder mask and the pads are covered with the conductive layer; forming a metal layer on the conductive layer by electroplating, wherein the first openings and the second openings are filled with the metal layer; performing a planarization step to remove the conductive layer and the metal layer located on the patterned photoresist layer so as to remain the conductive layer and the metal layer located in the first openings and the second openings; removing the patterned photoresist layer to expose the remaining conductive layer and the metal layer; and performing a reflow step to make the remaining conductive layer and the metal layer form a plurality of metal bumps.

According to a preferred embodiment of the present invention, the planarization step may be a chemical mechanical polishing (CMP) step.

With the application of the aforementioned method for forming metal bumps, a planarization step is used to prevent the height of the metal layer formed by electroplating from being non-uniform, so the poor uniformity in sizes of the metal bumps can be solved. Therefore, compared to the conventional process, the method of the present invention is more suitable for a package process with fine pitch, and is more effective for reducing the time and cost of the package process.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIGS. 1A through 1E are schematic flow diagrams showing the conventional process for manufacturing metal bumps; and

FIGS. 2A through 2E are schematic flow diagrams showing the process for manufacturing metal bumps in accordance with a preferred embodiment of the present invention.

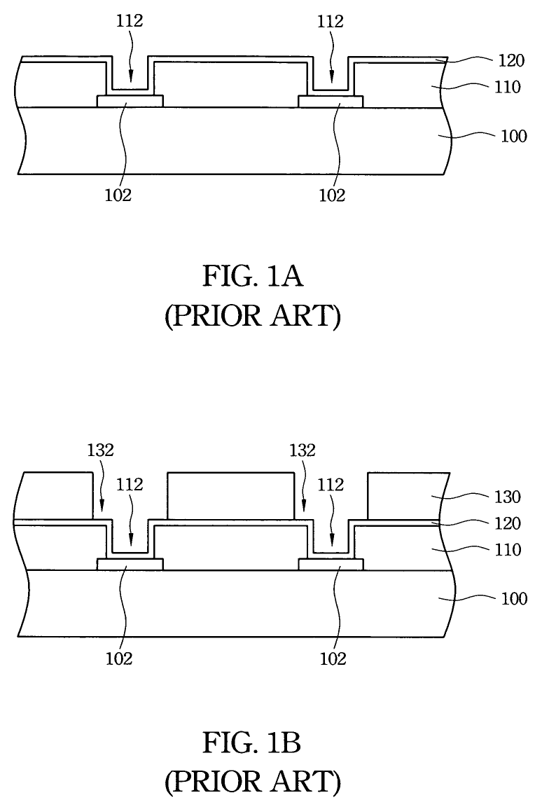

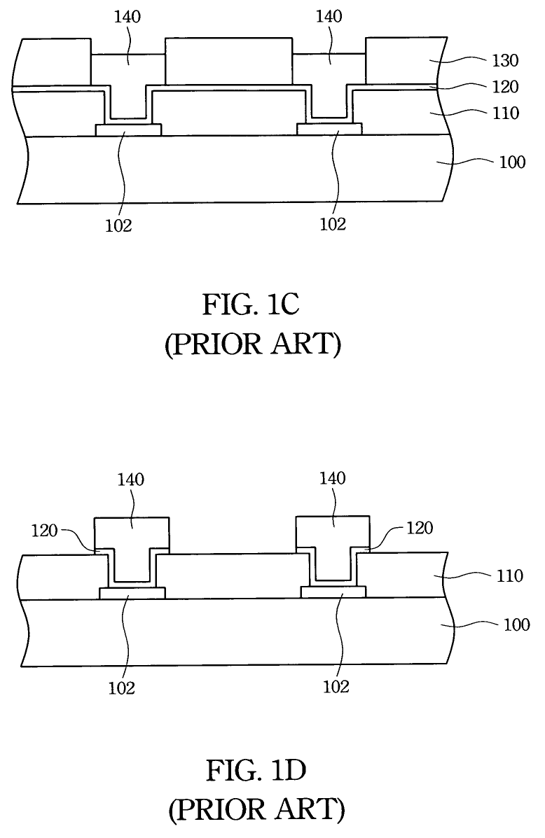

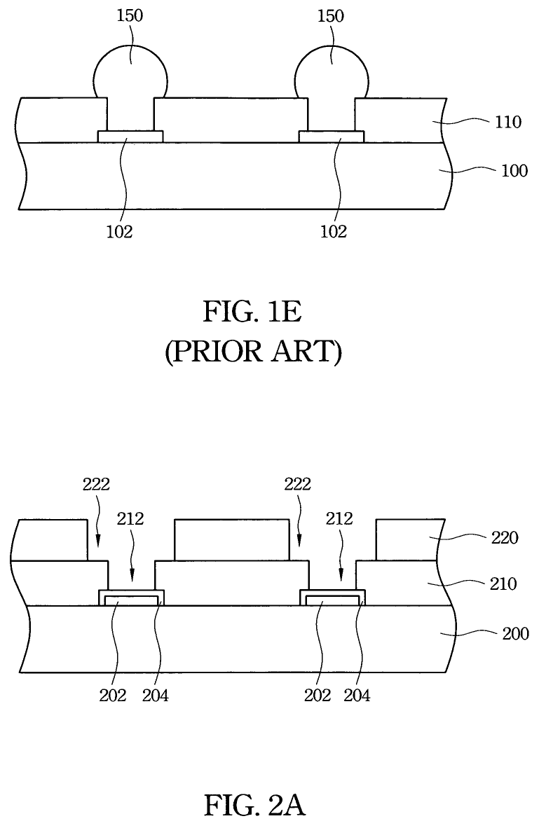

### DETAILED DESCRIPTION OF THE PREFERRED EMBODIMENT

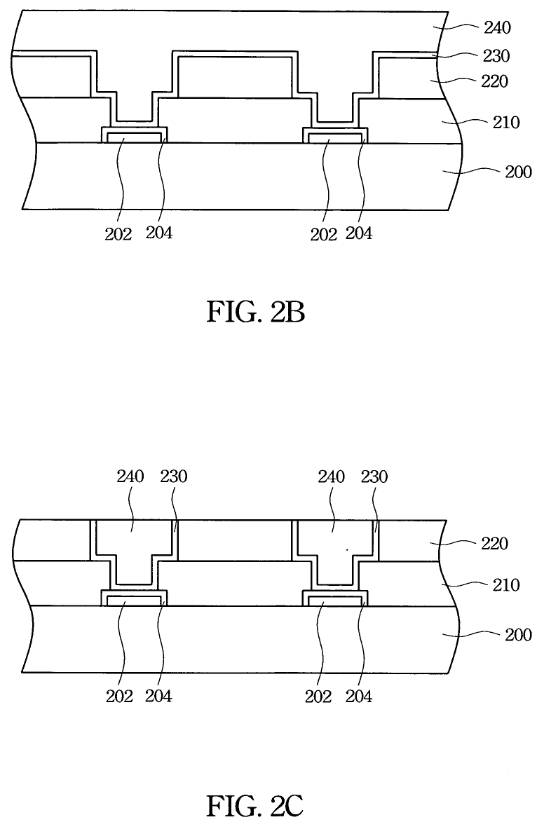

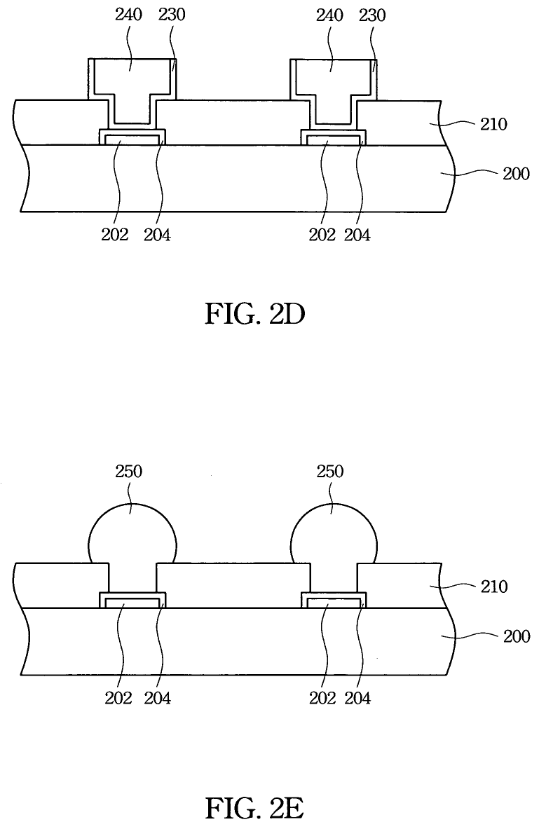

FIGS. 2A through 2E are schematic flow diagrams showing the process for manufacturing metal bumps in accordance with a preferred embodiment of the present invention. Firstly, such as shown in FIG. 2A, a substrate 200 is provided, wherein the substrate 200 includes a plurality of pads 202 formed thereon. In the embodiment, the substrate 200 is a printed circuit board, however, the other substrate including circuit set thereon may be used in the present invention, and the present invention is not limited thereto. In the embodiment, a protective layer 204 may be further formed on the pads 202 to increase the anti-oxidization of the pads 202, wherein a material of the protective layer 204 is selected from the group consisting of Au, Ni, Cu, Ag, Sn, Pb, Bi, Pd, Al, Fe, Cd, Zn and a combination thereof, or selected from organic solderability preservatives (OSP). Next, a patterned solder mask 210 is formed on the substrate 200, wherein the patterned solder mask 210 has a plurality of first openings 212 to expose the pads 202. In the embodiment, in the method of forming the patterned solder mask 210, a solder mask layer is initially formed to cover the substrate 200, and then a patterning step is performed (such as exposing and developing) on the layer of solder mask to form the plurality of first openings 212 to expose the pads 202. In the embodiment, a material of the solder mask 210 is green paint. A patterned photoresist layer 220 is formed on the patterned solder mask 210, wherein the patterned photoresist layer 220 has a plurality of second openings 222 to expose the pads 202. It is noteworthy that there is no limitation to the size relation between the second openings 222 and the first openings 212, and principally, the second openings 222 are greater than the first openings 212. In the embodiment, the photoresist layer 220 is a dry film or an organic film. In the step of forming the patterned photoresist layer 220, a photoresist layer is formed on the patterned solder mask 210, then an exposing and developing step is performed on the photoresist layer, and a portion of the photoresist layer is removed to form the patterned photoresist layer 220, wherein a method of forming the photoresist layer 220 is selected from the group consisting of printing, roller coating, spray coating, curtain coating and spin coating, and a light source may be used in the exposing and developing step is ultraviolet or laser. Then, such as shown in FIG. 2B, a conductive layer 230 is formed on the patterned photoresist layer 220, wherein a sidewall of each second opening 222 in the patterned photoresist layer 220, a sidewall of each first opening 212 in the patterned solder mask 210 and the pads 202 are covered with the conductive layer 230. In the embodiment, a material of the conductive layer 230 is selected from the group consisting of Au, Ni, Cu, Ag, Sn, Pb, Bi, Pd, Al, Fe, Cd, Zn and a combination thereof. A method of forming the conductive layer 230 is selected from the group consisting of vacuum sputtering, electroplating, chemical depositing and electroless plating. A metal layer 240 is formed on the conductive layer 230 by electroplating to fill up the first openings 212 and the second openings 222. In the embodiment, a material of the metal layer 240 is selected from the group consisting of Cu, Ag, Sn, Pb, Bi or a combination thereof. An electroplating method of the metal layer 240 is vertical electroplating or horizontal electroplating. Next, such as shown in FIG. 2C, a planarization step is performed to remove the conductive layer 230 and the metal layer 240 on the patterned photoresist layer 220 and to remain the conductive layer 230 and the metal layer 240 located in the first openings 212 and the second openings 222. In the embodiment, the planarization step may be a chemical mechanical polishing step, but is not limited thereto, and other precise planarization techniques may be used. Subsequently, such as shown in FIG. 2D, the patterned photoresist layer 220 is removed to expose the remaining conductive layer 230 and the metal layer 240. In the embodiment, a method of removing the patterned photoresist layer 220 is immersing or spraying an inorganic solution or an organic solution, wherein the inorganic solution is selected from the group consisting of NaOH, KOH and a combination thereof, and the organic solution is selected from the group consisting of acetone, NMP, DMSO, AE, DMA, DMF, THF and a combination thereof. Then, a reflow step is performed to make the remaining conductive layer 230 and the metal layer 240 form a plurality of metal bumps 250, such as shown in FIG. 2E. In the embodiment, the metal bumps 250 are composed of pre-solder.

In brief, a feature of the method for forming metal bumps in the present invention is that a planarization step is used to precisely control the thickness of the electroplating metal layer, so that the difference between the sizes of the metal bumps is negligible after the reflow step. As a result, the product yield of the fine pitch package process can be effectively enhanced. Therefore, the present invention can overcome the disadvantages of the prior art, and with the application of the method of the present invention, products of better quality can be obtained, and the time and the cost of the package fabrication can be effectively reduced.

According to the aforementioned preferred embodiments of the present invention, one advantage of applying the method for forming metal bumps of the present invention is that a planarization step is used to prevent the height of the metal layer formed by electroplating from being non-uniform, so that the poor uniformity in sizes of the metal bumps can be solved. Therefore, for products of fine pitch, the process of forming metal bumps of the present invention can solve the problems in the prior art. Therefore, the present invention can overcome the disadvantage of the prior art that the poor sizes uniformity of the metal bumps. Compared to the prior art, the method of forming metal bumps of the present invention is more suitable for a package process with fine pitch, and is more effective for reducing the time and cost of the package process.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method for forming metal bumps, comprising:
providing a substrate including a plurality of pads;
forming a solder mask on the substrate, wherein the solder mask has a plurality of first openings to expose the pads;
forming a photoresist layer on the solder mask, wherein the photoresist layer has a plurality of second openings to expose the pads;
forming a conductive layer on the phototresist layer, wherein a sidewall of each of the second openings in the photoresist layer, a sidewall of each of the first openings in the solder mask and the pads are covered with the conductive layer;
forming a metal layer on the conductive layer by electroplating, wherein the first openings and the second openings are filled up with the metal layer;
performing a planarization step to remove the conductive layer and the metal layer located on the photoresist layer so as to remain the conductive layer and the metal layer located in the first openings and the second openings; and
removing the photoresist layer to expose the remaining conductive layer and the remaining metal layer.

2. The method for forming metal bumps according to claim 1, further comprising a step of performing a reflow step to make the remaining conductive layer and the remaining metal layer form a plurality of metal bumps.

3. The method for forming metal bumps according to claim 1, wherein each of the metal bumps is pre-solder.

4. The method for forming metal bumps according to claim 1, wherein the step of providing the substrate comprises forming a protective layer on each of the pads.

5. The method for forming metal bumps according to claim 4, wherein a material of the protective layer is selected from the group consisting of Au, Ni, Cu, Ag, Sn, Pb, Bi, Pd, Al, Fe, Cd, Zn and a combination thereof.

6. The method for forming metal bumps according to claim 4, wherein a material of the protective layer is organic solderability preservatives.

7. The method for forming metal bumps according to claim 1, wherein a material of the solder mask is green paint, and the substrate is a printed circuit board.

8. The method for forming metal bumps according to claim 1, wherein the photoresist layer is a dry film or an organic film.

9. The method for forming metal bumps according to claim 1, wherein the step of forming the photoresist layer comprises:
forming a layer of photoresist on the solder mask;
performing an exposing and developing step on the photoresist layer; and
removing a portion of the layer of the photoresist to form the photoresist layer with the second openings.

10. The method for forming metal bumps according to claim 9, wherein a method of forming the layer of photoresist is selected from the group consisting of printing, roller coating, spray coating, curtain coating and spin coating.

11. The method for forming metal bumps according to claim 9, wherein a light source used in the exposing and developing step is ultraviolet or laser.

12. The method for forming metal bumps according to claim 1, wherein each of the second openings is greater than each of the first openings.

13. The method for forming metal bumps according to claim 1, wherein a method of forming the conductive layer is selected from the group consisting of vacuum sputtering, electroplating, chemical depositing and electroless plating.

14. The method for forming metal bumps according to claim 1, wherein a material of the conductive layer is selected from the group consisting of Au, Ni, Cu, Ag, Sn, Pb, Bi, Pd, Al, Fe, Cd, Zn and a combination thereof.

15. The method for forming metal bumps according to claim 1, wherein a method of forming the metal layer is vertical electroplating or horizontal electroplating.

16. The method for forming metal bumps according to claim 1, wherein a material of the metal layer is selected from the group consisting of Cu, Ag, Sn, Pb, Bi and a combination thereof.

17. The method for forming metal bumps according to claim 1, wherein the planarization step is performed by chemical mechanical polishing (CMP).

18. The method for forming metal bumps according to claim 1, wherein a method of removing the photoresist layer is immersing or spraying.

19. The method for forming metal bumps according to claim 1, wherein the step of removing the photoresist layer uses an inorganic solution, and the inorganic solution is selected from the group consisting of NaOH, KOH and a combination thereof.

20. The method for forming metal bumps according to claim 1, wherein the step of removing the photoresist layer uses an organic solution, and the organic solution is selected from the group consisting of acetone, NMP, DMSO, AE, DMA, DMF, THF and a combination thereof.
